(19) United States
(12) Patent Application Publication
(10) Pub. No.: US 2010/0123190 A1
(43) Pub. Date: May 20, 2010

(54) SEMICONDUCTOR DEVICE AND METHOD FOR MANUFACTURING THE SAME

(76) Inventor: BAEK WON KIM, Seoul (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/614,767

(22) Filed: Nov. 9, 2009

(30) Foreign Application Priority Data
Nov. 14, 2008 (KR) 10-2008-0113543

(51) Int. Cl. H01L 29/78; H01L 21/336

(52) U.S. Cl. 257/330; 438/270; 257/E21.41; 257/E29.262

(57) ABSTRACT

Provided are a semiconductor device and a method for manufacturing the same. In the method, a first conductive type buried layer and a first conductive type drift region are formed on a semiconductor substrate. A gate dielectric and gate electrode are formed in a first trench that extends into the first conductive type drift region. An oxide layer is formed on the semiconductor substrate, and first conductive type source regions are formed at sides of the gate electrode in a second conductive type well on the first conductive type drift region. An interlayer dielectric, the oxide layer, and the second conductive type well are selectively etched, forming a second trench. A tungsten plug is formed on a barrier layer in the second trench. Aluminum is buried on the tungsten plug to form a source contact. A drain electrode layer is formed connected to the first conductive type buried layer.

### CROSS-REFERENCE TO RELATED APPLICATION

This application claims the benefit under 35 U.S.C. §119 of Korean Patent Application No. 10-2008-0113543, filed Nov. 14, 2008, which is hereby incorporated by reference in its entirety.

### BACKGROUND

The present disclosure relates to a semiconductor device and a method for manufacturing the same.

A power transistor can have a vertical channel structure in which a source region of the power transistor is formed at an upper side of a semiconductor substrate, and a drain region is formed under the source region.

In regard to such a power transistor, various studies are being conducted to improve the operating characteristics according to a driving voltage by minimizing a distance between the source region and drain region of the power transistor.

### BRIEF SUMMARY

Embodiments provide a semiconductor device and a method for manufacturing the same.

Embodiments also provide a method for manufacturing a semiconductor device that can reduce a distance between a source region and a drain region of a transistor.

Embodiments also provide a method for manufacturing a semiconductor device that can efficiently form a contact of a source region of a transistor.

Embodiments also provide a method for manufacturing a semiconductor device that can inhibit a gate peeling due to an etch-off of a dielectric and a gate material from an over-etch of tungsten during a contact formation, thereby efficiently forming a contact of a source region and inhibiting a defect caused by a silicon peeling phenomenon.

In one embodiment, a method for manufacturing a semiconductor device comprises: forming a first conductive type buried layer in a semiconductor substrate, and a first conductive type drift region on the first conductive type buried layer; selectively removing a portion of the first conductive type drift region to form a first trench; forming a gate dielectric and a gate electrode in the first trench; forming a second conductive type well on the first conductive type drift region; forming an oxide layer on the semiconductor substrate; forming first conductive type source regions at sides of the gate electrode; forming an interlayer dielectric on the oxide layer; selectively etching portions of the interlayer dielectric, the oxide layer, and the second conductive type well to form a second trench; forming a barrier layer on the second trench; forming tungsten on the barrier layer; etching back the tungsten to form a tungsten plug in the second trench; burying aluminum on the tungsten plug to form a source contact; and forming a drain electrode layer electrically connected to the first conductive type buried layer.

In another embodiment, a semiconductor device comprises: a first conductive type buried layer on a semiconductor substrate, a first conductive type drift region on the first conductive type buried layer, and a second conductive type well on the first conductive type drift region; a gate dielectric and a gate electrode in a first trench, the first trench being formed by selectively removing portions of the second conductive type well and the first conductive type drift region from the semiconductor substrate; first conductive type source regions on the semiconductor substrate at sides of the gate electrode; an interlayer dielectric on the gate electrode and the first conductive type source region; a second trench formed by selectively removing a portion of the interlayer dielectric and the second conductive type well; a barrier layer on the semiconductor substrate including in the second trench; a plug at a lower part of the second trench and a source contact electrode at an upper part of the second trench; and a drain electrode layer on a real surface of the semiconductor substrate, the drain electrode layer being electrically connected to the first conductive type buried layer.

The details of one or more embodiments are set forth in the accompanying drawings and the description below. Other features will be apparent from the description and drawings, and from the claims.

### BRIEF DESCRIPTION OF THE DRAWINGS

FIGS. 1 through 16 are cross-sectional views illustrating a semiconductor device and a method for manufacturing the same according to an embodiment.

### DETAILED DESCRIPTION

Hereinafter, a semiconductor device and a method for manufacturing the same according to exemplary embodiments will be described in detail with reference to the accompanying drawings.

In the description of embodiments, it will be understood that when a layer (or film) is referred to as being ‘on/over’ another layer or substrate, it can be directly on the other layer or substrate, or intervening layers may also be present.

FIG. 16 is a view illustrating a semiconductor device according to an embodiment.

Referring to FIG. 16, a semiconductor device can include a first conductive type buried layer 9 and a first conductive type drift region 10. A second conductive type well 16 is formed on the first conductive type drift region 10.

A gate dielectric 13 and a gate electrode 14 are formed at a region where the first conductive type drift region 10 and the second conductive type well 16 are selectively removed. First conductive type source regions 18 are formed over the semiconductor substrate at sides of the gate electrode 14.

An oxide layer 15 and an interlayer dielectric 19 are formed over the first conductive type source region 18.

The second conductive type well 16 of the semiconductor substrate is partially etched to form a trench. The trench is formed at a side of the first conductive type source region 18. A barrier layer 22 is formed on the entire surface of the semiconductor substrate including the trench.

A metal material is buried on the barrier layer 22 in the trench is formed. In this embodiment, a tungsten (W) plug 23a and an aluminum contact electrode 24 are used as a source contact. A drain electrode layer 8 is formed under the first conductive type buried layer 9 of the semiconductor substrate.

As a power source is applied to the semiconductor device, electrons are moved through a vertical channel between the source region 18 and the drain electrode layer 8.

In accordance with an embodiment, the semiconductor device includes a trench for a source contact to reduce a distance between the source region 18 and the drain electrode layer 8. In this case, when aluminum is buried in the trench for a source contact, there is a high possibility that a void may occur. Accordingly, before an aluminum sputtering process, tungsten (W) is deposited through a Chemical Vapor Deposition (CVD) process to inhibit void formation.

After the deposition of tungsten, an etch-back process is performed to leave a tungsten plug 23a in the trench. A reactive ion etching process used in the etch-back process is performed with a high-selectivity etching of tungsten with respect to the barrier layer 22.

For example, if the barrier layer 22 is a Ti/TiN layer, a reactive ion etching process may be performed having a great difference of an etch rate of TiN:W=1:30 or more.

Thus, even after the reactive ion etching process is completed, the barrier layer 22 is not damaged, thereby inhibiting a silicon peeling and a dielectric or gate peeling.

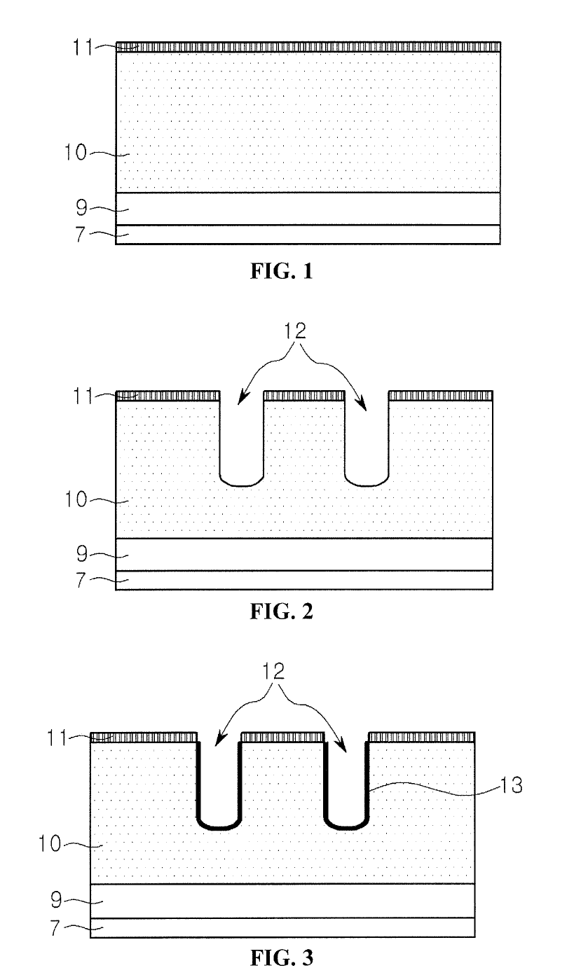

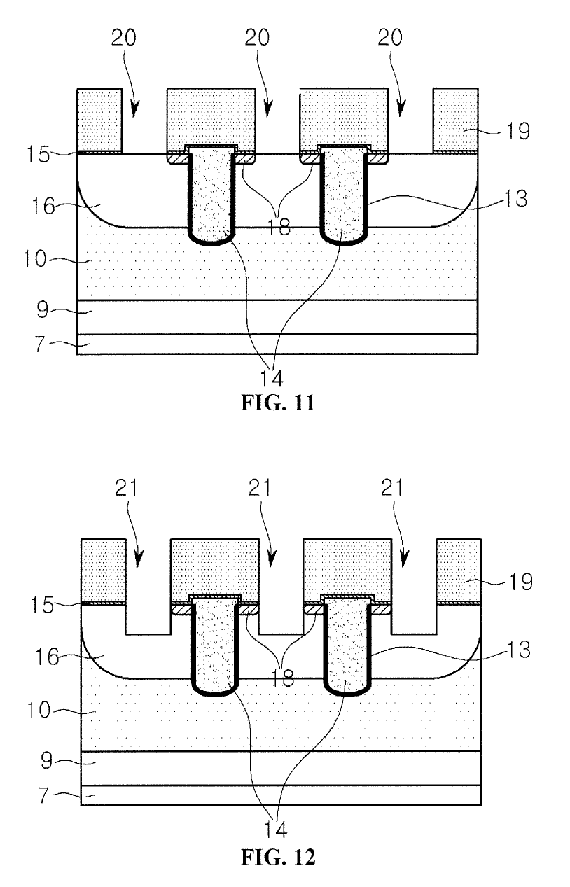

Hereinafter, a method for manufacturing a semiconductor device according to an embodiment will be described in detail with reference to FIGS. 1 through 16.

Referring to FIG. 1, a hard mask layer 11 may be formed on a semiconductor substrate 7 on which a first conductive type buried layer 9 and a first conductive type drift region 10 are formed. For example, the hard mask layer 11 may include an oxide or a nitride.

Referring to FIG. 2, after a photoresist pattern (not shown) is formed on the hard mask layer 11, a first trench 12 for forming a gate electrode 14 may be formed in the second conductive type drift region 10 through an etching process. Although two first trenches 12 for two gate electrodes 14 are shown in FIG. 2, the number of the first trenches 12 for forming the gate electrodes may be one or more.

Referring to FIG. 3, an oxide may be deposited in the first trench 12 for the gate electrode 14 to form a gate dielectric 13.

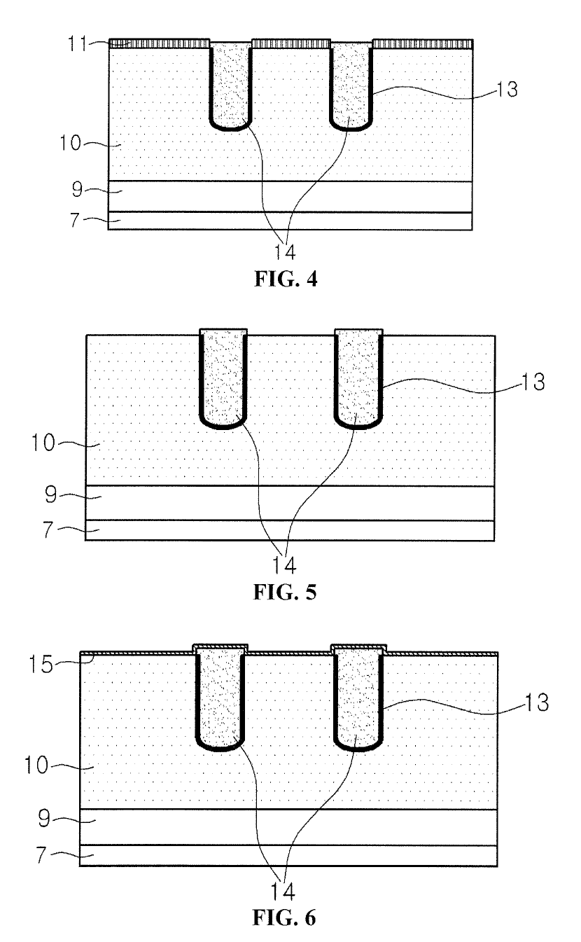

Referring to FIG. 4, polysilicon may be deposited on the semiconductor substrate including the first trench 12 on which the gate dielectric 13 is formed, and then the polysilicon may be etched to be buried in the first trench 12. Thus, the gate dielectric 13 and a gate electrode 14 are formed in the first trench 12.

Referring to FIGS. 5 and 6, the hard mask layer 11 formed on the semiconductor substrate may removed, and then an oxide layer 15 may be formed on the semiconductor substrate including the gate electrodes 14. The oxide layer 15 may be used to isolate the gate electrodes 14 and protect the semiconductor substrate 7 (with the first conductive type buried layer 9 and the first conductive type drift region 10) from a damage caused in a subsequent impurity implantation process.

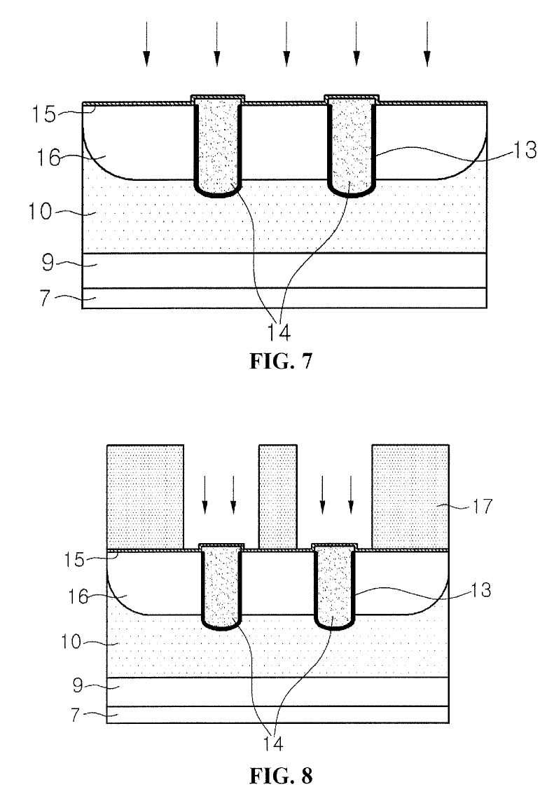

Referring to FIG. 7, second conductive type impurity ions can be implanted into the semiconductor substrate, and may be heat-treated to form the second conductive type well 16 in which the second conductive type impurity ions are diffused.

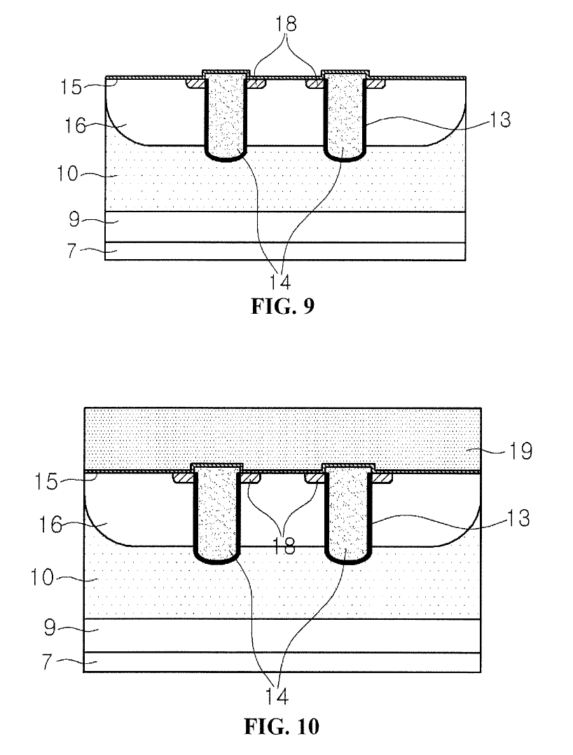

Referring to FIGS. 8 and 9, a photoresist layer pattern 17 may be formed on the semiconductor substrate to expose regions for forming a source of the transistor. After first conductive type impurities ions are implanted, the photoresist pattern 17 may be removed.

Then, a heat-treatment may be performed on the semiconductor substrate to form first conductive type source regions 18 at sides of the gate electrode 14.

Referring to FIGS. 10 through 12, an interlayer dielectric 19 may be formed on the semiconductor substrate, and a photoresist pattern (not shown) may be formed on the interlayer dielectric 19. Then, the interlayer dielectric 19 and the oxide layer 15 may be selectively removed using the photoresist pattern (not shown) as a mask to form a second trench 20.

Next, the second conductive type well 16 exposed by the second trench 20 may be selectively removed using the interlayer dielectric 19 and the oxide layer 15 as a mask to form a third trench 21.

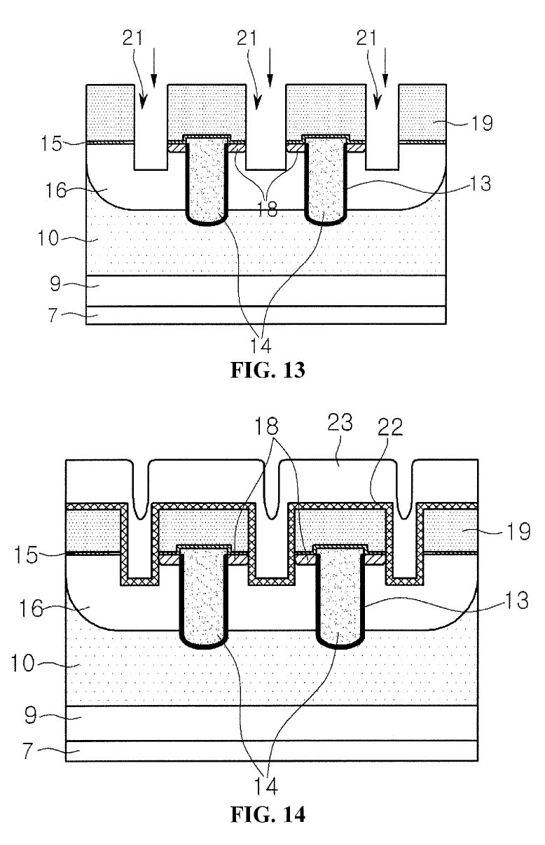

Referring to FIG. 13, second conductive type impurity ions may be implanted into the second conductive type well 16 exposed by the third trench 21 to inhibit a leakage current.

Referring to FIG. 14, a barrier layer 22 may be formed on the semiconductor substrate including the third trench 21. Then, tungsten 23 may be deposited through a CVD method to gap-fill a portion of the third trench 21.

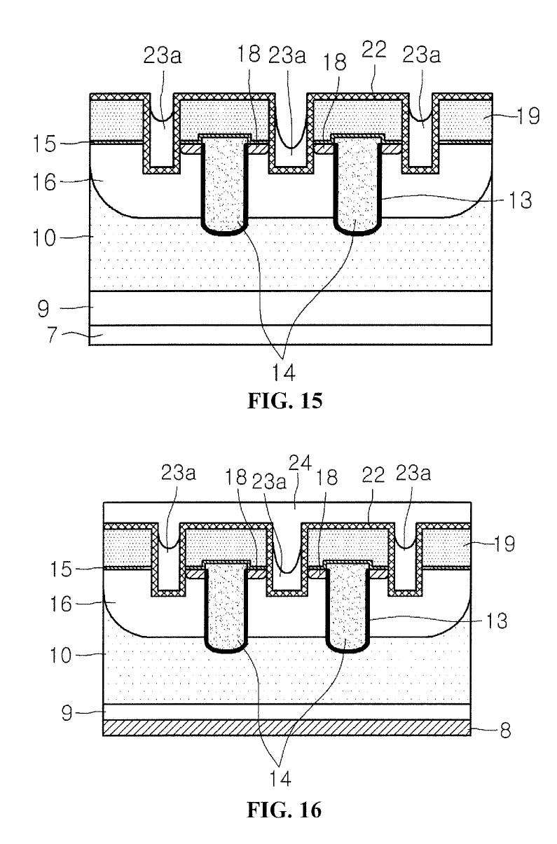

Referring to FIG. 15, the tungsten 23 may be etched back to leave a tungsten plug 23a in the trench.

The etch-back process may be performed through a reactive ion etching process, and may be performed through a single process.

The reactive ion etching process used in the etch-back process may be performed with a high selectivity etching of the tungsten 23 with respect to the barrier layer 22.

For example, if the barrier layer 22 is a Ti/TiN layer, a reactive ion etching process may be performed having a great difference of an etch rate of TiN:W=1:30 or more.

For this, the reactive ion etching process may satisfy a pressure of about 100 mT to about 200 mT, an RF power of about 100 Watt to about 500 Watt, SF₆ flow rate of about 50 sccm to about 300 sccm, and argon (Ar) flow rate of about 50 sccm to about 300 sccm. Also, an argon base etching process satisfying an etch selectivity of SF₆:Ar of about 1:1 to about 1:4 may be performed.

Thus, even after the reactive ion etching process is completed, the barrier layer 22 is not damaged, thereby inhibiting a silicon peeling and a dielectric or gate peeling.

Particularly, the third trench 21 between the gate electrodes 14 may have a greater width than other trenches. The third trench 21 having a relatively wider width can inhibit a defect generation and a short fail due to a peeling by a silicon etch-off at a lower film of the tungsten plug 23a.

Thus, when the tungsten 23 is deposited through a CVD process, a possibility that a void occurs in the third trench 21 is reduced.

Referring to FIG. 16, aluminum 24 having a low resistance may be deposited and etched on the tungsten plug 23a to form a source contact including the tungsten plug 23a and an aluminum contact electrode.

Subsequently, a drain electrode layer 8 electrically connected to the first conductive type buried layer 9 of the semiconductor substrate may be formed by performing a back-grinding process of the semiconductor substrate to expose the first conductive type buried layer 9 and forming the drain electrode layer on the exposed surface of the first conductive type buried layer.

As described above, the semiconductor device according to embodiments can minimize a contact resistance according to a high operating voltage in a power transistor having a source region 18 and a drain electrode layer 8 that are disposed in a vertical direction. Also, a portion of the semiconductor substrate may be etched to form a trench for minimizing a distance between the source region 18 and the drain electrode layer 8, and a source contact may be formed therein.

Since there is a possibility that a void may occur if the source contact is formed in the trench through an aluminum sputtering process, the trench may be gap-filled with tungsten through a CVD process, and then the source contact may be formed through an aluminum sputtering process.

According to embodiments, the performance of a semiconductor device can be improved by minimizing a contact resistance according to a high operating voltage and reducing a distance between a source region and a drain region. Also, a gate peeling due to an etch-off of a dielectric and a gate by an over-etch of tungsten can be inhibited in a contact formation, thereby efficiently forming a contact of a source region and inhibit a defect caused by a silicon peeling phenomenon.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, comprising:
forming a first conductive type buried layer in a semiconductor substrate, and a first conductive type drift region on the first conductive type buried layer;
selectively removing a portion of the first conductive type drift region to form a first trench;
forming a gate dielectric and a gate electrode in the first trench;
forming a second conductive type well on the first conductive type drift region;
forming an oxide layer on the semiconductor substrate including on the gate electrode;
forming first conductive type source regions at sides of the gate electrode;
forming an interlayer dielectric on the oxide layer;
selectively etching portions of the interlayer dielectric, the oxide layer, and the second conductive type well to form a second trench;
forming a barrier layer on the semiconductor substrate including in the trench;
forming tungsten on the barrier layer;
etching back the tungsten to form a tungsten plug in the trench;
burying aluminum on the tungsten plug to form a source contact; and
forming a drain electrode layer electrically connected to the first conductive type buried layer.

2. The method according to claim 1, wherein the etching-back of the tungsten comprises performing a single reactive etching process.

3. The method according to claim 1, wherein the barrier layer comprises a Ti/TiN layer.

4. The method according to claim 1, wherein the etching-back of the tungsten comprises an etching process that satisfies a pressure of about 100 mT to about 200 mT, an RF power of about 100 Watt to about 500 Watt, SF₆ flow rate of about 50 sccm to about 300 sccm, and Ar flow rate of about 50 sccm to about 300 sccm.

5. The method according to claim 4, wherein, in the etching process, a ratio of SF₆:Ar ranges from about 1:1 to about 1:4.

6. The method according to claim 1, wherein selectively removing the portion of the first conductive type drift region to form the first trench comprises:
forming and patterning a hard mask layer on the semiconductor substrate;
etching the first conductive type drift region using the hard mask layer as an etch mask; and
removing the hard mask layer.

7. The method according to claim 1, wherein the forming of the first conductive type source regions comprises:
forming a photoresist pattern on the oxide layer, the photoresist pattern exposing the gate electrode and the second conductive type well at sides of the gate electrode;
implanting first conductive type impurity ions using the photoresist pattern as a mask;
removing the photoresist pattern; and
heat-treating the semiconductor substrate to diffuse the first conductive type impurity ions.

8. The method according to claim 1, wherein the forming of the tungsten on the barrier layer comprises depositing tungsten using a Chemical Vapor Deposition (CVD) process.

9. The method according to claim 1, wherein the burying of the aluminum comprises performing a sputtering process.

10. The method according to claim 1, further comprising implanting second conductive type impurity ions in the second trench before the forming of the barrier layer on the second trench.

11. The method according to claim 1, wherein the tungsten fills a portion of the trench, and the aluminum fills other portion of the trench that is not filled with the tungsten.

12. The method according to claim 1, wherein forming the drain electrode layer comprises:
back-grinding the semiconductor substrate to expose the first conductive type buried layer; and
contacting the drain electrode layer to the exposed first conductive type buried layer.

13. A semiconductor device comprising:
a first conductive type buried layer on a semiconductor substrate, a first conductive type drift region on the first conductive type buried layer, and a second conductive type well on the first conductive type drift region;
a gate dielectric and a gate electrode in a first trench, the first trench being formed by selectively removing a portion of the second conductive type well and the first conductive type drift region from the semiconductor substrate;
first conductive type source regions on the semiconductor substrate at sides of the gate electrode;
an interlayer dielectric on the gate electrode and the first conductive type source region;
a second trench formed by selectively removing a portion of the interlayer dielectric and the second conductive type well;
a barrier layer on the semiconductor substrate including in the second trench;
a plug at a lower part of the second trench and a source contact electrode at an upper part of the second trench; and
a drain electrode layer contacting a surface of the semiconductor substrate, the drain electrode layer being electrically connected to the first conductive type buried layer.

14. The semiconductor device according to 13, wherein the source contact electrode comprises aluminum.

15. The semiconductor device according to 13, wherein the plug comprises tungsten.
